(19) United States
(12) Patent Application Publication
(10) Pub. No.: US 2022/0128715 A1
(43) Pub. Date: Apr. 28, 2022

(54) RADIATION DETECTOR WITH QUANTUM DOT SCINTILLATORS

(71) Applicant: SHENZHEN XPECTVISION TECHNOLOGY CO., LTD., Shenzhen (CN)

(72) Inventors: Peiyan CAO, Shenzhen (CN); Yurun LIU, Shenzhen (CN)

(21) Appl. No.: 17/571,727

(22) Filed: Jan. 10, 2022

Related U.S. Application Data
(63) Continuation of application No. PCT/CN2019/097935, filed on Jul. 26, 2019.

(51) Int. Cl. G01T 1/20; G01T 1/15

(52) U.S. Cl. CPC G01T 1/2018; G01T 1/2002; G01T 1/15

(57) ABSTRACT

Disclosed herein is a method comprising: forming one or more blobs within a footprint of a pixel of a photodetector; wherein the blobs comprise quantum dots configured to emit a pulse of visible light upon absorbing a particle of radiation; wherein the pixel is configured to detect the pulse of visible light. Also disclosed herein is a radiation detector, comprising: an array of discrete blobs with quantum dots configured to emit a pulse of visible light upon absorbing a particle of radiation; an electronic system configured to detect the particle of radiation by detecting the pulse of visible light.

### BACKGROUND

A radiation detector is a device that measures a property of a radiation. Examples of the property may include a spatial distribution of the intensity, phase, and polarization of the radiation. The radiation may be one that has interacted with a subject. For example, the radiation measured by the radiation detector may be a radiation that has penetrated or reflected from the subject. The radiation may be an electromagnetic radiation such as infrared light, visible light, ultraviolet light, X-ray or γ-ray. The radiation may be of other types such as α-rays and β-rays.

### SUMMARY

Disclosed herein is a method comprising: forming one or more blobs within a footprint of a pixel of a photodetector; wherein the blobs comprise quantum dots configured to emit a pulse of visible light upon absorbing a particle of radiation; wherein the pixel is configured to detect the pulse of visible light.

According to an embodiment, the blobs are discrete from one another.

According to an embodiment, forming the one or more blobs comprises propelling one or more droplets onto the pixel, the one or more droplets comprising the quantum dots.

According to an embodiment, the quantum dots are selected from a group consisting of lead iodide (PbI) quantum dots, CdZnTe (CZT) quantum dots, cesium iodide (CsI) quantum dots, bismuth germanate (BGO) quantum dots, cadmium tungstate CdWO4 quantum dots, calcium tungstate (CaWO4) quantum dots, gadolinium oxysulfide (Gd2O2S) quantum dots, cerium doped lanthanum bromide (LaBr3(Ce)) quantum dots, cerium doped lanthanum chloride (LaCl3(Ce)) quantum dots, lead tungstate (PbWO4) quantum dots lutetium oxyorthosilicate (Lu2SiO5 or LSO) quantum dots, Lu1.8Y0.2SiO5(Ce) (LYSO) quantum dots, thallium doped sodium iodide (NaI(TI)) quantum dots, yttrium aluminum garnet (YAG(Ce)) quantum dots, zinc sulfide (ZnS(Ag)) quantum dots, zinc tungstate (ZnWO4) quantum dots, and combinations thereof.

According to an embodiment, the pixel is separated from other pixels of the photodetector by a material opaque to visible light.

According to an embodiment, the pixel is separated from other pixels of the photodetector by a material opaque to the radiation.

According to an embodiment, the particle of radiation is an X-ray photon.

Disclosed herein is a radiation detector, comprising: an array of discrete blobs with quantum dots configured to emit a pulse of visible light upon absorbing a particle of radiation; an electronic system configured to detect the particle of radiation by detecting the pulse of visible light.

According to an embodiment, the quantum dots are selected from a group consisting of lead iodide (PbI) quantum dots, CdZnTe (CZT) quantum dots, cesium iodide (CsI) quantum dots, bismuth germanate (BGO) quantum dots, cadmium tungstate CdWO4 quantum dots, calcium tungstate (CaWO4) quantum dots, gadolinium oxysulfide (Gd2O2S) quantum dots, cerium doped lanthanum bromide (LaBr3(Ce)) quantum dots, cerium doped lanthanum chloride (LaCl3(Ce)) quantum dots, lead tungstate (PbWO4) quantum dots lutetium oxyorthosilicate (Lu2SiO5 or LSO) quantum dots, Lu1.8Y0.2SiO5(Ce) (LYSO) quantum dots, thallium doped sodium iodide (NaI(TI)) quantum dots, yttrium aluminum garnet (YAG(Ce)) quantum dots, zinc sulfide (ZnS(Ag)) quantum dots, zinc tungstate (ZnWO4) quantum dots, and combinations thereof.

According to an embodiment, the radiation detector further comprises a visible light absorption layer configured to generate an electric signal upon absorbing the pulse of visible light; wherein the electronic system is configured to detect the pulse of visible light through the electric signal.

According to an embodiment, the visible light absorption layer is divided into discrete regions by a material opaque to visible light.

According to an embodiment, the visible light absorption layer is divided into discrete regions by a material opaque to the radiation.

According to an embodiment, the discrete blobs are separated by a material opaque to visible light.

According to an embodiment, the discrete blobs are separated by a material opaque to the radiation.

According to an embodiment, the electronic system is configured to count a number of particles of radiation absorbed by the discrete blobs by counting a number of pulses of visible light.

According to an embodiment, the visible light absorption layer comprises a plurality of pixels.

According to an embodiment, the electronic system comprises a counter configured to count a number of pulses of visible light received by a pixel of the plurality of pixels.

According to an embodiment, at least one of the discrete blobs is within a footprint of each pixel.

According to an embodiment, the electronic system comprises an analog-to-digital converter (ADC) configured to digitize the electric signal.

According to an embodiment, the ADC is a successive-approximation-register (SAR) ADC.

According to an embodiment, the particle of radiation is an X-ray photon.

According to an embodiment, the visible light absorption layer comprises an electric contact; wherein the electronic system comprises: a first voltage comparator configured to compare a voltage of the electric contact to a first threshold; a second voltage comparator configured to compare the voltage to a second threshold; a counter configured to register a number of pulses of visible light received by the visible light absorption layer; a controller, wherein the controller is configured to start a time delay from a time at which the first voltage comparator determines that an absolute value of the voltage equals or exceeds an absolute value of the first threshold; wherein the controller is configured to activate the second voltage comparator during the time delay; wherein the controller is configured to cause the number of pulses of visible light registered by the counter to increase by one, upon determination by the second voltage comparator that an absolute value of the voltage equals or exceeds an absolute value of the second threshold.

According to an embodiment, the radiation detector further comprises an integrator electrically connected to the electric contact, wherein the integrator is configured to collect charge carriers from the electric contact.

According to an embodiment, the controller is configured to activate the second voltage comparator at a beginning or expiration of the time delay.

According to an embodiment, the controller is configured to connect the electric contact to an electrical ground.

According to an embodiment, a rate of change of the voltage is substantially zero at expiration of the time delay.

According to an embodiment, the visible light absorption layer comprises a diode.

According to an embodiment, the visible light absorption layer comprises silicon or germanium.

Disclosed herein is a system comprising the radiation detector above, and a radiation source, wherein the system is configured to perform radiography on human chest or abdomen.

Disclosed herein is a system comprising the radiation detector above, and a radiation source, wherein the system is configured to perform radiography on human mouth and teeth.

Disclosed herein is a cargo scanning or non-intrusive inspection (NII) system, comprising the radiation detector above, and a radiation source, wherein the cargo scanning or non-intrusive inspection (NII) system is configured to form an image using radiation transmitted through an object inspected.

Disclosed herein is a full-body scanner system comprising the radiation detector above, and a radiation source.

Disclosed herein is a computed tomography (CT) system comprising the radiation detector above, and a radiation source.

### BRIEF DESCRIPTION OF FIGURES

FIG. 1A schematically shows a cross-sectional view of a radiation detector, according to an embodiment.

FIG. 1B schematically shows a detailed cross-sectional view of the radiation detector.

FIG. 1C schematically shows an alternative detailed cross-sectional view of the radiation detector.

FIG. 2 schematically shows a top view of a portion of the radiation detector, according to an embodiment.

FIG. 3A and FIG. 3B each schematically show a component diagram of an electronic system of the radiation detector, according to an embodiment.

FIG. 4 schematically shows a temporal change of an electric current flowing through an electric contact (upper curve) caused by charge carriers generated by a pulse of visible light incident on a pixel associated with the electric contact, and a corresponding temporal change of the voltage of the electric contact (lower curve).

FIG. 5A-FIG. 5B schematically show a method of making the radiation detector, according to an embodiment.

FIG. 6A schematically shows that a single visible light absorption layer bonded to a single electronic layer, according to an embodiment.

FIG. 6B schematically shows multiple chips bonded to a single electronic layer, wherein each chip may include a visible light absorption layer, according to an embodiment.

FIG. 7-FIG. 11 each schematically show a system comprising the radiation detector described herein.

### DETAILED DESCRIPTION

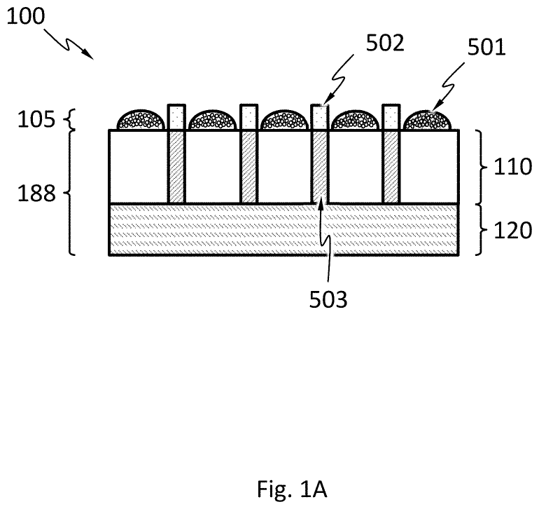

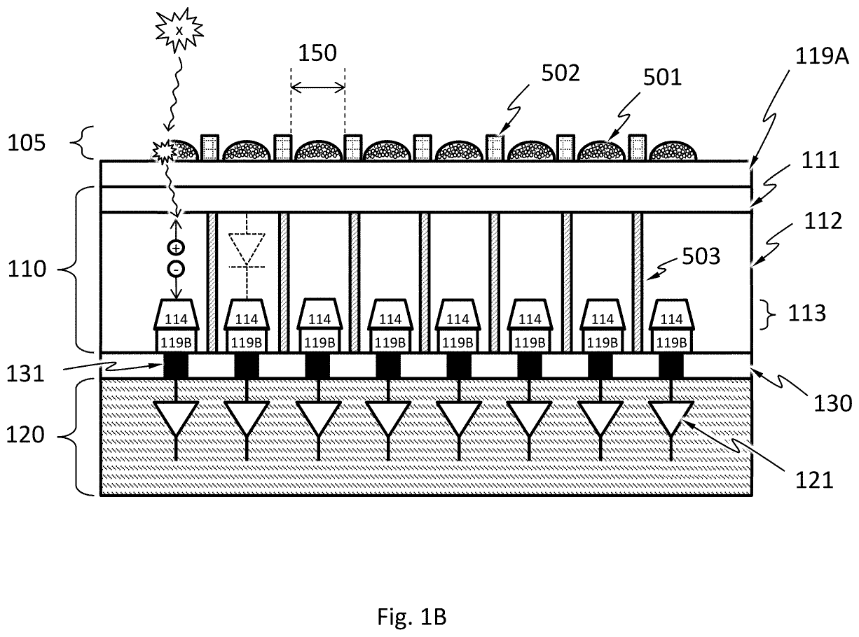

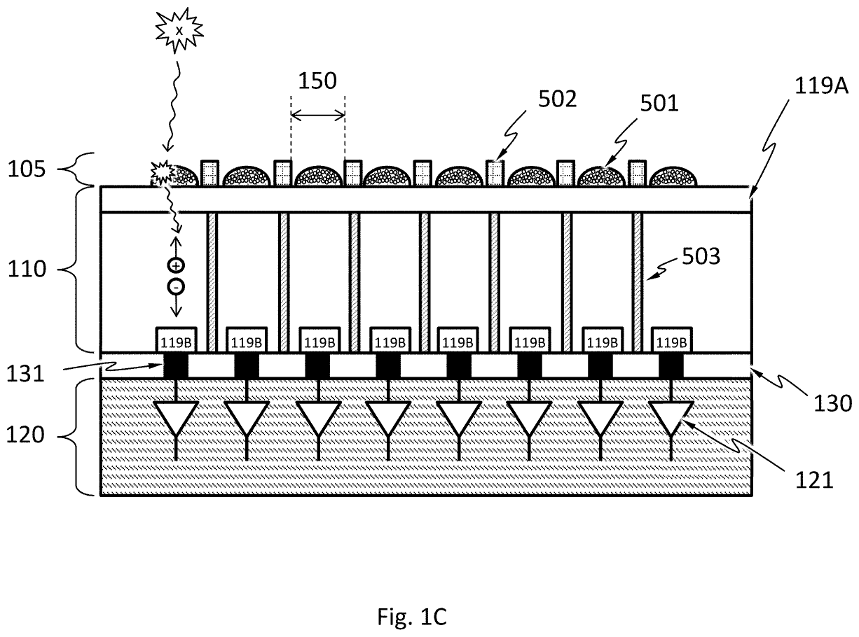

FIG. 1A schematically shows a cross-sectional view of a radiation detector 100, according to an embodiment. The radiation detector 100 includes a layer 105 comprising an array of discrete blobs 501 with quantum dots. The quantum dots are configured to emit a pulse of visible light upon absorbing a particle of radiation. The radiation detector 100 has an electronics layer 120 (e.g., an ASIC) with an electronic system configured to detect the particle of radiation by detecting the pulse of visible light.

The radiation detector 100 may have a visible light absorption layer 110 configured to generate an electric signal upon absorbing the pulse of visible light. The visible light absorption layer 110 may include a semiconductor material such as silicon, germanium, or a combination thereof. The semiconductor material may have a high mass attenuation coefficient for the visible light emitted from the quantum dots. The visible light absorption layer 110 may be divided into discrete regions by a barrier 503 with a material opaque to the visible light, opaque to the radiation, or opaque to both. The electronic system may detect the pulse of visible light through the electric signal. The electronics layer 120 and the visible light absorption layer 110 may be parts of a photodetector 188.

Each discrete blob 501 may include a plurality of quantum dots such as lead iodide (PbI) quantum dots, CdZnTe (CZT) quantum dots, cesium iodide (CsI) quantum dots, bismuth germanate (BGO) quantum dots, cadmium tungstate CdWO₄ quantum dots, calcium tungstate (CaWO₄) quantum dots, gadolinium oxysulfide (Gd₂O₂S) quantum dots, cerium doped lanthanum bromide (LaBr₃(Ce)) quantum dots, cerium doped lanthanum chloride (LaCl₃(Ce)) quantum dots, lead tungstate (PbWO₄) quantum dots lutetium oxyorthosilicate (Lu₂SiO₅ or LSO) quantum dots, Lu_{1.8}Y_{0.2}SiO₅(Ce) (LYSO) quantum dots, thallium doped sodium iodide (NaI(TI)) quantum dots, yttrium aluminum garnet (YAG(Ce)) quantum dots, zinc sulfide (ZnS(Ag)) quantum dots, and zinc tungstate (ZnWO₄) quantum dots. The discrete blobs 501 may be separated from one another by a barrier 502 that comprises a material opaque to the visible light, opaque to the radiation, or opaque to both.

As shown in a detailed cross-sectional view of the radiation detector 100 in FIG. 1B, according to an embodiment, the blobs 501 of quantum dots may emit a pulse of visible light when a particle of radiation incident thereon is absorbed. One example of the mechanism for the emission of the pulse of visible light is fluorescence. The particle of radiation may be an X-ray photon. The pulse of visible light emitted from the quantum dots may be directed toward the visible light absorption layer 110. The visible light absorption layer 110 may include one or more diodes (e.g., p-i-n or p-n) formed by a first doped region 111, one or more discrete regions 114 of a second doped region 113. The second doped region 113 may be separated from the first doped region 111 by an optional the intrinsic region 112. The discrete regions 114 are separated from one another by the first doped region 111 or the intrinsic region 112. The first doped region 111 and the second doped region 113 have opposite types of doping (e.g., region 111 is p-type and region 113 is n-type, or region 111 is n-type and region 113 is p-type). In the example in FIG. 1B, each of the discrete regions 114 of the second doped region 113 forms a diode with the first doped region 111 and the optional intrinsic region 112. Namely, in the example in FIG. 1B, the visible light absorption layer 110 has a plurality of diodes having the first doped region 111 as a shared electrode. The first doped region 111 may also have discrete portions.

When the pulse of visible light emitted from the quantum dots of a blob 501 hits the visible light absorption layer 110 including diodes, the visible light may be absorbed and generate one or more charge carriers by a number of mechanisms. A pulse of visible light may generate 1 to 100000 charge carriers. The charge carriers may drift to the electrodes of one of the diodes under an electric field. The field may be an external electric field. The electrical contact 119B may include discrete portions each of which is in electrical contact with the discrete regions 114. In an embodiment, the charge carriers may drift in directions such that the charge carriers generated by a single pulse of visible light are not substantially shared by two different discrete regions 114 (“not substantially shared” here means less than 2%, less than 0.5%, less than 0.1%, or less than 0.01% of these charge carriers flow to a different one of the discrete regions 114 than the rest of the charge carriers). A pixel 150 associated with a discrete region 114 may be an area around the discrete region 114 in which substantially all (more than 98%, more than 99.5%, more than 99.9%, or more than 99.99% of) charge carriers generated by a pulse of visible light therein flow to the discrete region 114. Namely, less than 2%, less than 1%, less than 0.1%, or less than 0.01% of these charge carriers flow beyond the pixel. In an embodiment, within the footprint of each pixel 150 there is one or more of the blobs 501 of quantum dots.

As shown in an alternative detailed cross-sectional view of the radiation detector 100 in FIG. 1C, according to an embodiment, the visible light absorption layer 110 may include a resistor of a semiconductor material such as, silicon, germanium, or a combination thereof, but does not include a diode. The semiconductor may have a high mass attenuation coefficient for the visible light emitted from the blobs 501 of quantum dots.

When the pulse of visible light from the quantum dots of a blob 501 hits the visible light absorption layer 110 including a resistor but not diodes, it may be absorbed and generate one or more charge carriers by a number of mechanisms. A pulse of visible light may generate 1 to 100000 charge carriers. The charge carriers may drift to the electric contacts 119A and 119B under an electric field. The field may be an external electric field. The electric contact 119B includes discrete portions. In an embodiment, the charge carriers may drift in directions such that the charge carriers generated by a single pulse of visible light are not substantially shared by two different discrete portions of the electric contact 119B (“not substantially shared” here means less than 2%, less than 0.5%, less than 0.1%, or less than 0.01% of these charge carriers flow to a different one of the discrete portions than the rest of the charge carriers). A pixel 150 associated with a discrete portion of the electric contact 119B may be an area around the discrete portion in which substantially all (more than 98%, more than 99.5%, more than 99.9% or more than 99.99% of) charge carriers generated by a pulse of visible light incident therein flow to the discrete portion of the electrical contact 119B. Namely, less than 2%, less than 0.5%, less than 0.1%, or less than 0.01% of these charge carriers flow beyond the pixel associated with the one discrete portion of the electric contact 119B. In an embodiment, within the footprint of each pixel 150 there is one or more of the blobs 501 of quantum dots.

The electronic system 121 is configured to count a number of particles of radiation absorbed by the blobs 501 of quantum dots by counting a number of pulses of visible light emitted from the blobs 501 of quantum dots, according to an embodiment. The electronic system 121 may include an analog circuitry such as a filter network, amplifiers, integrators, and comparators, or a digital circuitry such as a microprocessor, and memory. The electronic system 121 may include components shared by the pixels or components dedicated to a single pixel. For example, the electronic system 121 may include an amplifier dedicated to each pixel and a microprocessor shared among all the pixels. The electronic system 121 may be electrically connected to the electric contacts 119B by vias 131. Space among the vias may be filled with a filler material 130, which may increase the mechanical stability of the connection of the electronics layer 120 to the visible light absorption layer 110. Other bonding techniques are possible to connect the electronic system 121 to the pixels 150 without using vias.

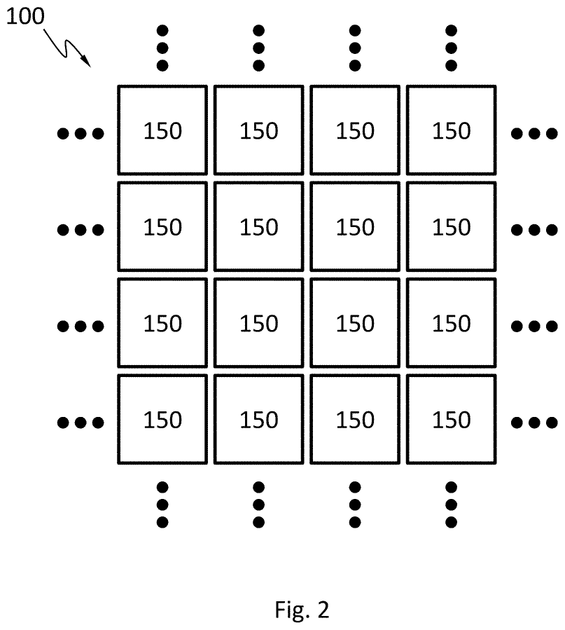

FIG. 2 schematically shows that pixels 150 in the radiation detector 100 may be arranged in an array, according to an embodiment. The array may be a rectangular array, a honeycomb array, a hexagonal array or any other suitable array. The electronic system 121 may be configured to detect incident pulses of visible light thereon using the pixels 150. In one embodiment, the numbers of pulses of visible light incident on all the pixels 150 within the same period of time are counted by a counter included in the electronic system 121. An analog-to-digital converter (ADC) may be configured to digitize an analog signal representing the characteristic of the pulse of visible light incident on each pixel 150. The pixels 150 may be configured to operate in parallel. For example, when one pixel 150 has a pulse of visible light incident thereon, another pixel 150 may or may not have a pulse of visible light incident thereon. The pixels 150 may not have to be individually addressable. The radiation detector 100 may have at least 100, 2500, 10000, or more pixels 150.

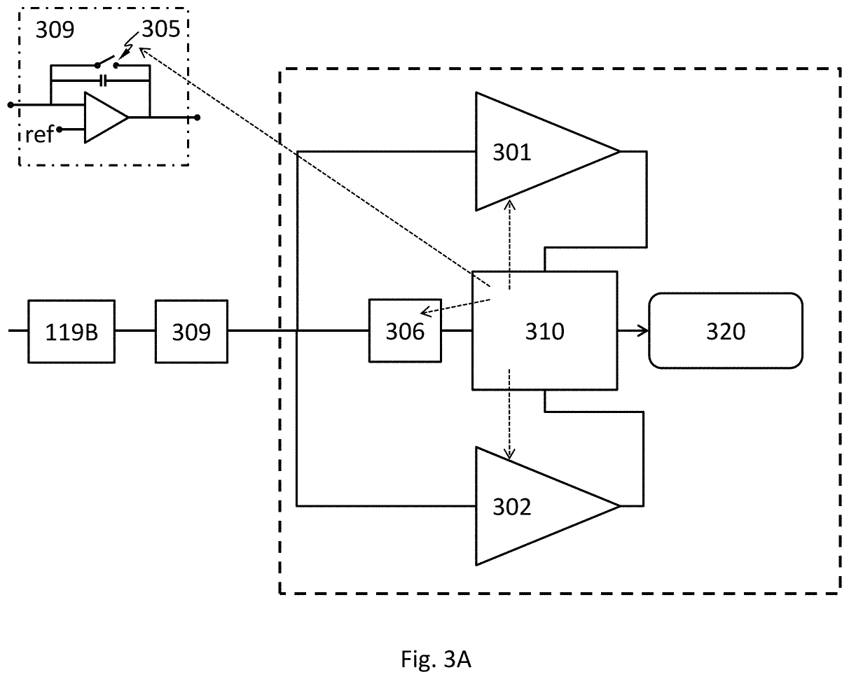

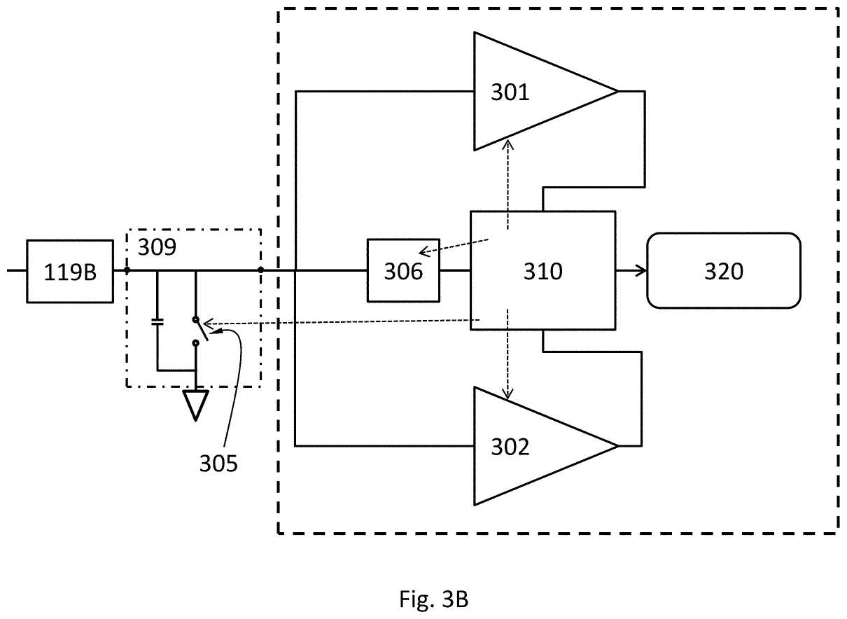

FIG. 3A and FIG. 3B each schematically show a component diagram of the electronic system 121, according to an embodiment. The electronic system 121 may include a first voltage comparator 301, a second voltage comparator 302, a counter 320, a switch 305, an ADC 306 and a controller 310.

The first voltage comparator 301 is configured to compare the voltage of the electric contact 119B to a first threshold. The first voltage comparator 301 may be configured to monitor the voltage directly, or calculate the voltage by integrating an electric current flowing through the electric contact over a period of time. The first voltage comparator 301 may be controllably activated or deactivated by the controller 310. The first voltage comparator 301 may be a continuous comparator. Namely, the first voltage comparator 301 may be configured to be activated continuously, and monitor the voltage continuously. The first voltage comparator 301 configured as a continuous comparator reduces the chance of the electronic system 121 missing signals generated by a pulse of visible light. The first voltage comparator 301 may be a clocked comparator, which has the benefit of lower power consumption. The first threshold may be 5-10%, 10%-20%, 20-30%, 30-40% or 40-50% of the voltage a single pulse of visible light may generate on the electrical contact. The maximum voltage may depend on the energy of the pulse of visible light, the material of the visible light absorption layer 110, and other factors. For example, the first threshold may be 50 mV, 100 mV, 150 mV, or 200 mV.

The second voltage comparator 302 is configured to compare the voltage to a second threshold. The second voltage comparator 302 may be configured to monitor the voltage directly, or calculate the voltage by integrating an electric current flowing through the diode or the electrical contact over a period of time. The second voltage comparator 302 may be controllably activate or deactivated by the controller 310. When the second voltage comparator 302 is deactivated, the power consumption of the second voltage comparator 302 may be less than 1%, less than 5%, less than 10% or less than 20% of the power consumption when the second voltage comparator 302 is activated. The absolute value of the second threshold is greater than the absolute value of the first threshold. As used herein, the term “absolute value” or “modulus” |x| of a real number x is the non-negative value of x without regard to its sign. Namely,

$$\vert x \vert = \{ \begin{matrix}x , if x \geq 0 \\ - x , if x \leq 0\end{matrix} .$$

The second threshold may be 200%-300% of the first threshold. The second threshold may be at least 50% of the maximum voltage one pulse of visible light may generate on the electric contact 119B. For example, the second threshold may be 100 mV, 150 mV, 200 mV, 250 mV or 300 mV. The second voltage comparator 302 and the first voltage comparator 301 may be the same component. Namely, the system 121 may have one voltage comparator that can compare a voltage with two different thresholds at different times.

The first voltage comparator 301 or the second voltage comparator 302 may include one or more op-amps or any other suitable circuitry.

The counter 320 is configured to register a number of pulses of visible light received by the visible light absorption layer 110. The counter 320 may be a software component (e.g., a number stored in a computer memory) or a hardware component (e.g., a 4017 IC and a 7490 IC).

The controller 310 may be a hardware component such as a microcontroller and a microprocessor. The controller 310 is configured to start a time delay from a time at which the first voltage comparator 301 determines that the absolute value of the voltage equals or exceeds the absolute value of the first threshold (e.g., the absolute value of the voltage increases from below the absolute value of the first threshold to a value equal to or above the absolute value of the first threshold). The absolute value is used here because the voltage may be negative or positive, depending on whether the voltage of the cathode or the anode of the diode or which electric contact is used. The controller 310 may be configured to keep deactivated the counter 320 and any other circuits the operation of the first voltage comparator 301 does not require, before the time at which the first voltage comparator 301 determines that the absolute value of the voltage equals or exceeds the absolute value of the first threshold. The time delay may expire before or after the voltage becomes stable, i.e., the rate of change of the voltage is substantially zero. The phase “the rate of change of the voltage is substantially zero” means that temporal change of the voltage is less than 0.1%/ns. The phase “the rate of change of the voltage is substantially non-zero” means that temporal change of the voltage is at least 0.1%/ns.

The controller 310 may be configured to activate the second voltage comparator during (including the beginning and the expiration) the time delay. In an embodiment, the controller 310 is configured to activate the second voltage comparator at the beginning or expiration of the time delay. The term “to activate a component” means causing the component to enter an operational state (e.g., by sending a signal such as a voltage pulse or a logic level, by providing power, etc.). The term “to deactivate a component” means causing the component to enter a non-operational state (e.g., by sending a signal such as a voltage pulse or a logic level, by cut off power, etc.). The operational state may have higher power consumption (e.g., 10 times higher, 100 times higher, 1000 times higher) than the non-operational state. The controller 310 itself may be deactivated until the output of the first voltage comparator 301 activates the controller 310 when the absolute value of the voltage equals or exceeds the absolute value of the first threshold.

The controller 310 may be configured to cause the number registered by the counter 320 to increase by one, if, during the time delay, the second voltage comparator 302 determines that the absolute value of the voltage equals or exceeds the absolute value of the second threshold.

The controller 310 may be configured to cause the ADC 306 to digitize the voltage upon expiration of the time delay and determine based on the voltage which bin the energy of the particle of radiation falls in.

The controller 310 may be configured to connect the electric contact 119B to an electrical ground, so as to reset the voltage and discharge any charge carriers accumulated on the electrical contact. In an embodiment, the electric contact 119B is connected to an electrical ground after the expiration of the time delay. In an embodiment, the electric contact is connected to an electrical ground for a finite reset time period. The controller 310 may connect the electric contact 119B to the electrical ground by controlling the switch 305. The switch may be a transistor such as a field-effect transistor (FET).

In an embodiment, the system 121 has no analog filter network (e.g., a RC network). In an embodiment, the system 121 has no analog circuitry.

The ADC 306 may feed the voltage it measures to the controller 310 as an analog or digital signal. The ADC may be a successive-approximation-register (SAR) ADC (also called successive approximation ADC). An SAR ADC digitizes an analog signal via a binary search through all possible quantization levels before finally converging upon a digital output for the analog signal. An SAR ADC may have four main subcircuits: a sample and hold circuit to acquire the input voltage (Vᵢₙ), an internal digital-analog converter (DAC) configured to supply an analog voltage comparator with an analog voltage equal to the digital code output of the successive approximation register (SAR), the analog voltage comparator that compares Vᵢₙ to the output of the internal DAC and outputs the result of the comparison to the SAR, the SAR configured to supply an approximate digital code of Vᵢₙ to the internal DAC. The SAR may be initialized so that the most significant bit (MSB) is equal to a digital 1. This code is fed into the internal DAC, which then supplies the analog equivalent of this digital code (V_{ref}/2) into the comparator for comparison with Vᵢₙ. If this analog voltage exceeds Vᵢₙ the comparator causes the SAR to reset this bit; otherwise, the bit is left a 1. Then the next bit of the SAR is set to 1 and the same test is done, continuing this binary search until every bit in the SAR has been tested. The resulting code is the digital approximation of Vᵢₙ and is finally output by the SAR at the end of the digitization.

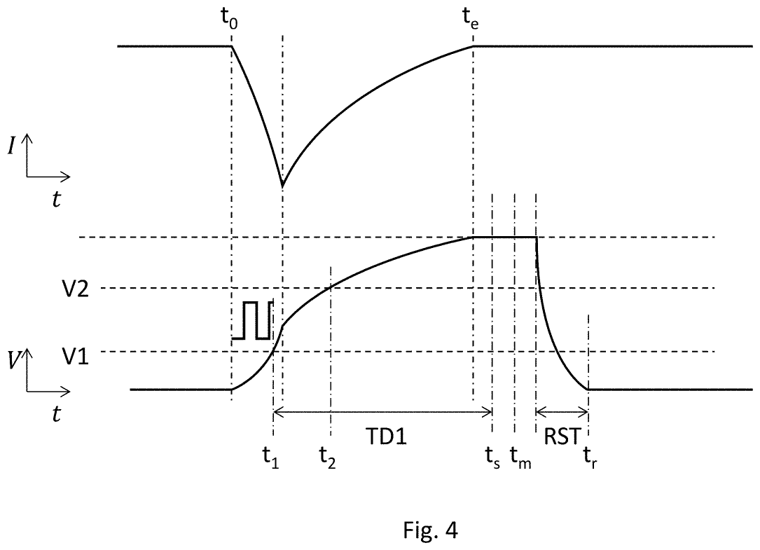

The electronic system 121 may include an integrator 309 electrically connected to the electrode of the diode or the electric contact, wherein the integrator is configured to collect charge carriers from the electrode of the diode or the electric contact. The integrator can include a capacitor in the feedback path of an amplifier. The amplifier configured as such is called a capacitive transimpedance amplifier (CTIA). CTIA has high dynamic range by keeping the amplifier from saturating and improves the signal-to-noise ratio by limiting the bandwidth in the signal path. Charge carriers from the electrode or the electric contact accumulate on the capacitor over a period of time (“integration period”) (e.g., as shown in FIG. 4, between t₀ to t₁). After the integration period has expired, the capacitor voltage is sampled by the ADC 306 and then reset by a reset switch. The integrator can include a capacitor directly connected to the electrode or the electric contact.

FIG. 4 schematically shows a temporal change of electric currents flowing through the electric contact 119B (upper curve) caused by charge carriers generated by a pulse of visible light, and a corresponding temporal change of the voltage of the electric contact 119B (lower curve). The voltage may be an integral of the electric current with respect to time. At time t₀, a radiation particle hits the detector, a pulse of visible light is emitted from the quantum dots of a blob 501; the pulse of visible light is absorbed at a pixel 150 of the visible light absorption layer 110; charge carriers start being generated in the visible light absorption layer 110 associated with the pixel 150; electric current starts to flow through the electric contact 119B; and the absolute value of the voltage of the electric contact 119B starts to increase. At time t₁, the first voltage comparator 301 determines that the absolute value of the voltage equals or exceeds the absolute value of the first threshold V1, and the controller 310 starts the time delay TD1 and the controller 310 may deactivate the first voltage comparator 301 at the beginning of TD1. If the controller 310 is deactivated before t₁, the controller 310 is activated at t₁. During TD1, the controller 310 activates the second voltage comparator 302. The term “during” a time delay as used here means the beginning and the expiration (i.e., the end) and any time in between. For example, the controller 310 may activate the second voltage comparator 302 at the expiration of TD1. If during TD1, the second voltage comparator 302 determines that the absolute value of the voltage equals or exceeds the absolute value of the second threshold at time t₂, the controller 310 waits for stabilization of the voltage to stabilize. The voltage stabilizes at time tₑ, when all charge carriers generated by the pulse of visible light drift out of the visible light absorption layer 110. At time tₛ, the time delay TD1 expires. At or after time tₑ, the controller 310 causes the ADC 306 to digitize the voltage and determines which bin the energy of the particle of radiation falls in. The controller 310 then causes the number registered by the counter 320 corresponding to the bin to increase by one. In the example of FIG. 4, time tₛ is after time tₑ; namely TD1 expires after all charge carriers generated by the visible light drift out of the visible light absorption layer 110. If time tₑ cannot be easily measured, TD1 can be empirically chosen to allow sufficient time to collect essentially all charge carriers generated by a pulse of visible light but not too long to risk have another pulse of visible light. Namely, TD1 can be empirically chosen so that time tₛ is empirically after time tₑ. Time tₛ is not necessarily after time tₑ because the controller 310 may disregard TD1 once V2 is reached and wait for time tₑ. The rate of change of the difference between the voltage and the contribution to the voltage by the dark current is thus substantially zero at tₑ. The controller 310 may be configured to deactivate the second voltage comparator 302 at expiration of TD1 or at t2, or any time in between.

The voltage at time tₑ is proportional to the amount of charge carriers generated by the pulse of visible light, which relates to the energy of the particle of radiation. The controller 310 may be configured to determine the bin the energy of the particle of radiation falls in, based on the output of the ADC 306.

After TD1 expires or digitization by the ADC 306, whichever later, the controller 310 connects the electric contact 119B to an electric ground for a reset period RST to allow charge carriers accumulated on the electric contact 119B to flow to the ground and reset the voltage. After RST, the electronic system 121 is ready to detect another incident particle of radiation.

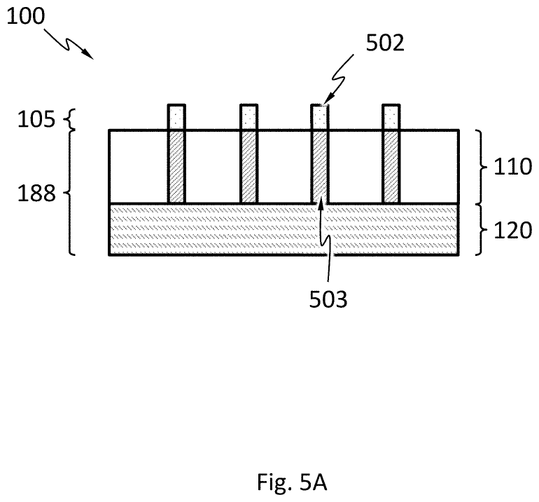

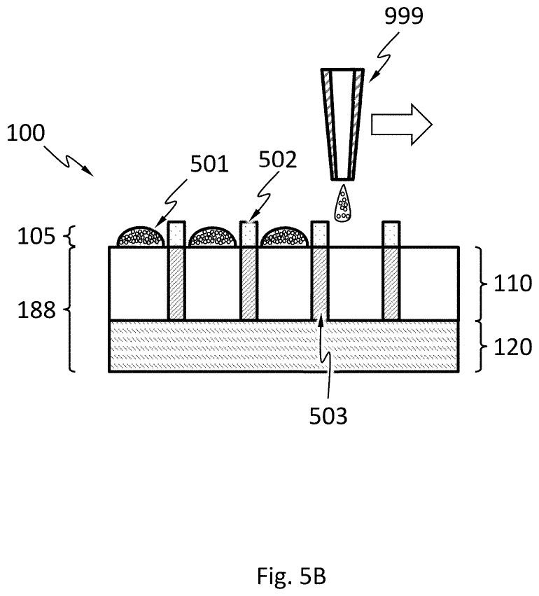

FIG. 5A-FIG. 5B schematically show a method of making the radiation detector 100. The photodetector 188 is obtained first. Then, one or more of the blobs 501 are formed onto the photodetector 188 within a footprint of a pixel of the photodetector 188. Forming the blobs 501 onto the photodetector 188 may include propelling one or more droplets on to the pixel, the one or more droplets comprising the quantum dots. For example, the blobs 501 may be printed onto the photodetector 188 by a inkjet 999.

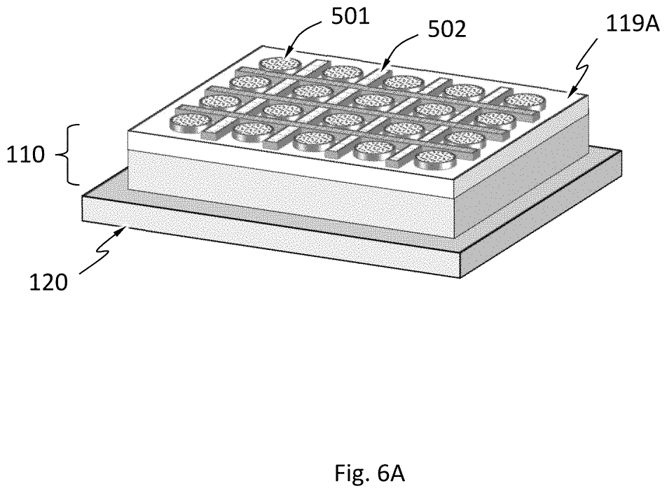

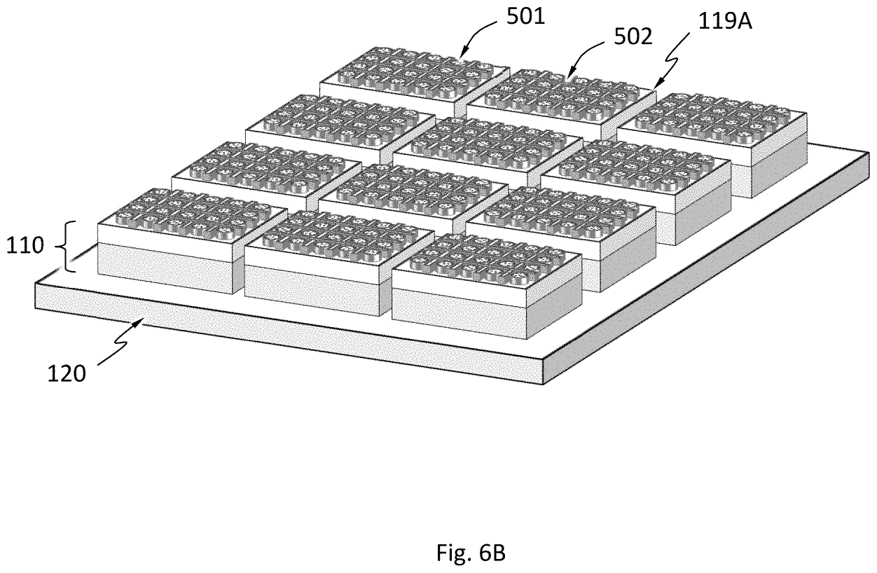

FIG. 6A shows that the visible light absorption layer 110 may be a single piece bonded to the electronic layer 120, according to an embodiment. FIG. 6B shows that the visible light absorption layer 110 may include multiple discrete chips bonded to the electronic layer 120, according to an embodiment.

The radiation detector 100 described above may be used in various systems such as those provided below.

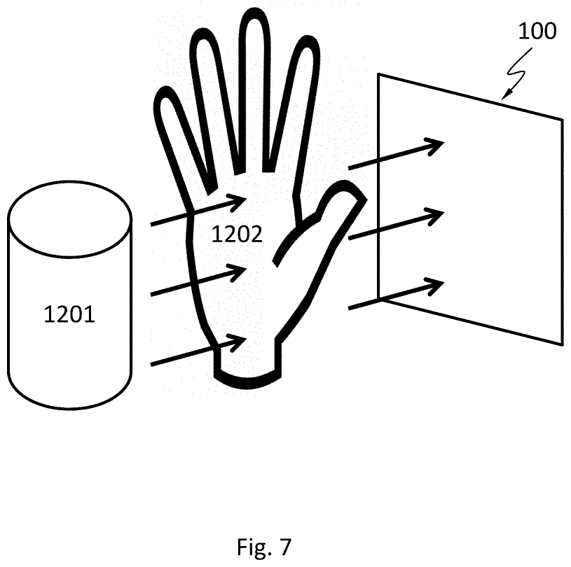

FIG. 7 schematically shows a system comprising the radiation detector 100 described herein. The system may be used for medical imaging such as chest radiography, abdominal radiography, etc. The system comprises a radiation source 1201 that emits radiation. Radiation emitted from the radiation source 1201 penetrates an object 1202 (e.g., a human body part such as chest, limb, abdomen), is attenuated by different degrees by the internal structures of the object 1202 (e.g., bones, muscle, fat and organs, etc.), and is projected to the radiation detector 100. The radiation detector 100 forms an image by detecting the intensity distribution of the radiation.

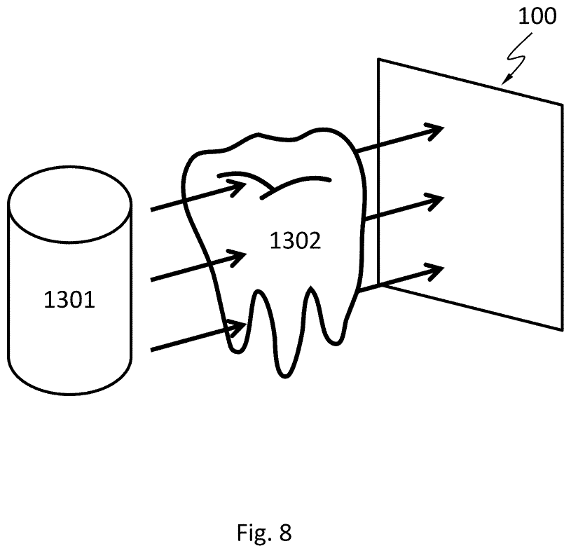

FIG. 8 schematically shows a system comprising the radiation detector 100 described herein. The system may be used for medical imaging such as dental radiography. The system comprises a radiation source 1301 that emits radiation. Radiation emitted from the radiation source 1301 penetrates an object 1302 that is part of a mammal (e.g., human) mouth. The object 1302 may include a maxilla bone, a palate bone, a tooth, the mandible, or the tongue. The radiation is attenuated by different degrees by the different structures of the object 1302 and is projected to the radiation detector 100. The radiation detector 100 forms an image by detecting the intensity distribution of the radiation. Teeth absorb radiation more than dental caries, infections, periodontal ligament. The dosage of radiation received by a dental patient is typically small (around 0.150 mSv for a full mouth series).

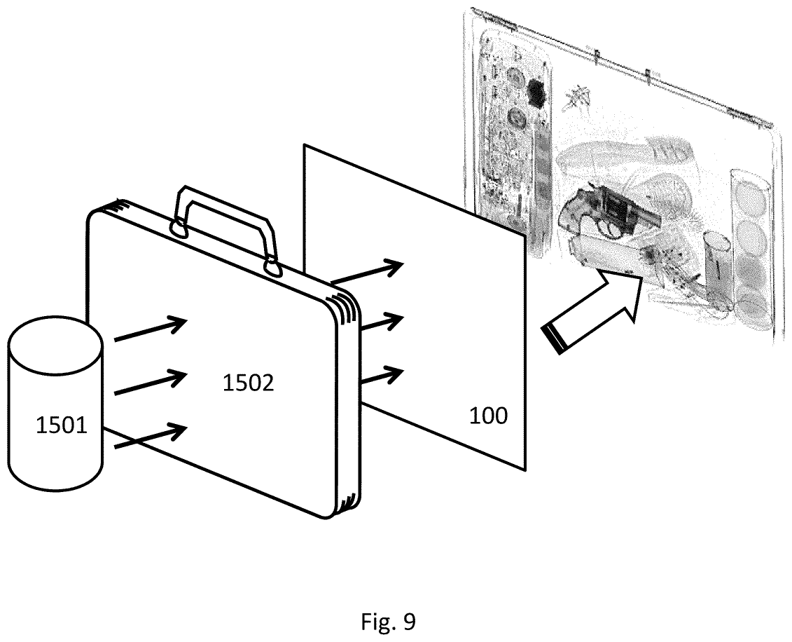

FIG. 9 schematically shows a cargo scanning or non-intrusive inspection (NII) system comprising the radiation detector 100 described herein. The system may be used for luggage screening at public transportation stations and airports. The system comprises a radiation source 1501 that emits radiation. Radiation emitted from the radiation source 1501 may penetrate a piece of luggage 1502, be differently attenuated by the contents of the luggage, and projected to the radiation detector 100. The radiation detector 100 forms an image by detecting the intensity distribution of the transmitted radiation. The system may reveal contents of luggage and identify items forbidden on public transportation, such as firearms, narcotics, edged weapons, flammables.

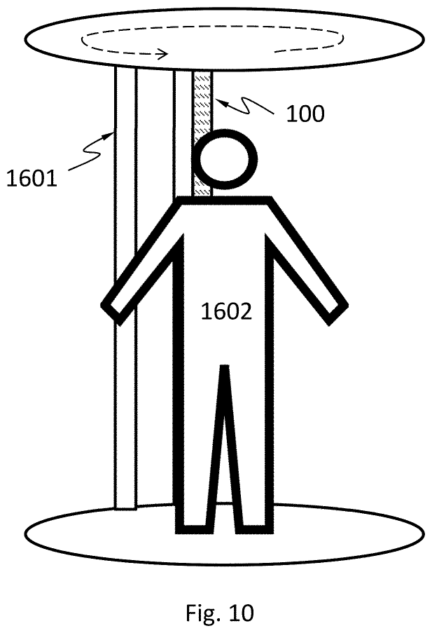

FIG. 10 schematically shows a full-body scanner system comprising the radiation detector 100 described herein. The full-body scanner system may detect objects on a person's body for security screening purposes, without physically removing clothes or making physical contact. The full-body scanner system may be able to detect non-metal objects. The full-body scanner system comprises a radiation source 1601. The radiation emitted from the radiation source 1601 may backscatter from a human 1602 being screened and objects thereon, and be projected to the radiation detector 100. The objects and the human body may backscatter the radiation differently. The radiation detector 100 forms an image by detecting the intensity distribution of the backscattered radiation. The radiation detector 100 and the pulsed radiation source 1601 may be configured to scan the human in a linear or rotational direction.

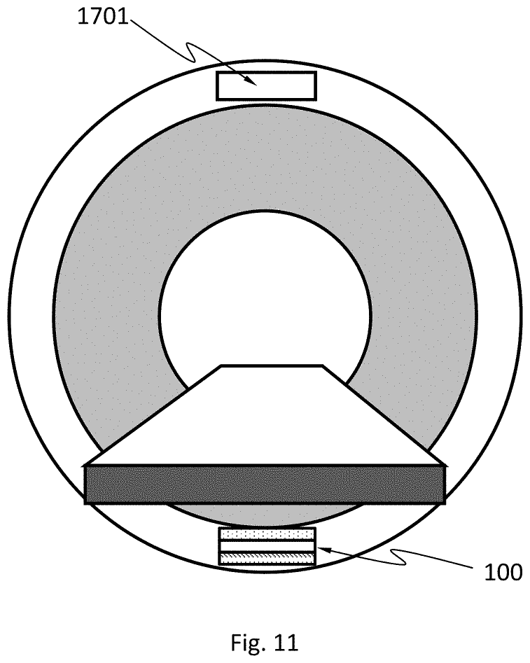

FIG. 11 schematically shows a radiation computed tomography (Radiation CT) system. The radiation CT system uses computer-processed radiations to produce tomographic images (virtual “slices”) of specific areas of a scanned object. The tomographic images may be used for diagnostic and therapeutic purposes in various medical disciplines, or for flaw detection, failure analysis, metrology, assembly analysis and reverse engineering. The radiation CT system comprises the radiation detector 100 described herein and a pulsed radiation source 1701 that emits radiation. The radiation detector 100 and the pulsed radiation source 1701 may be configured to rotate synchronously along one or more circular or spiral paths.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A method comprising:
forming one or more blobs within a footprint of a pixel of a photodetector;
wherein the blobs comprise quantum dots configured to emit a pulse of visible light upon absorbing a particle of radiation;
wherein the pixel is configured to detect the pulse of visible light.

2. The method of claim 1, wherein the blobs are discrete from one another.

3. The method of claim 1, wherein forming the one or more blobs comprises propelling one or more droplets onto the pixel, the one or more droplets comprising the quantum dots.

4. The method of claim 1, wherein the quantum dots are selected from a group consisting of lead iodide (PbI) quantum dots, CdZnTe (CZT) quantum dots, cesium iodide (CsI) quantum dots, bismuth germanate (BGO) quantum dots, cadmium tungstate CdWO₄ quantum dots, calcium tungstate (CaWO₄) quantum dots, gadolinium oxysulfide (Gd₂O₂S) quantum dots, cerium doped lanthanum bromide (LaBr₃(Ce)) quantum dots, cerium doped lanthanum chloride (LaCl₃(Ce)) quantum dots, lead tungstate (PbWO₄) quantum dots lutetium oxyorthosilicate (Lu₂SiO₅ or LSO) quantum dots, Lu_{1.8}Y_{0.2}SiO₅(Ce) (LYSO) quantum dots, thallium doped sodium iodide (NaI(TI)) quantum dots, yttrium aluminum garnet (YAG(Ce)) quantum dots, zinc sulfide (ZnS(Ag)) quantum dots, zinc tungstate (ZnWO₄) quantum dots, and combinations thereof.

5. The method of claim 1, wherein the pixel is separated from other pixels of the photodetector by a material opaque to visible light.

6. The method of claim 1, wherein the pixel is separated from other pixels of the photodetector by a material opaque to the radiation.

7. The method of claim 1, wherein the particle of radiation is an X-ray photon.

8. A radiation detector, comprising:
an array of discrete blobs with quantum dots configured to emit a pulse of visible light upon absorbing a particle of radiation;
an electronic system configured to detect the particle of radiation by detecting the pulse of visible light.

9. The radiation detector of claim 8, wherein the quantum dots are selected from a group consisting of lead iodide (PbI) quantum dots, CdZnTe (CZT) quantum dots, cesium iodide (CsI) quantum dots, bismuth germanate (BGO) quantum dots, cadmium tungstate CdWO₄ quantum dots, calcium tungstate (CaWO₄) quantum dots, gadolinium oxysulfide (Gd₂O₂S) quantum dots, cerium doped lanthanum bromide (LaBr₃(Ce)) quantum dots, cerium doped lanthanum chloride (LaCl₃(Ce)) quantum dots, lead tungstate (PbWO₄) quantum dots lutetium oxyorthosilicate (Lu₂SiO₅ or LSO) quantum dots, Lu_{1.8}Y_{0.2}SiO₅(Ce) (LYSO) quantum dots, thallium doped sodium iodide (NaI(TI)) quantum dots, yttrium aluminum garnet (YAG(Ce)) quantum dots, zinc sulfide (ZnS(Ag)) quantum dots, zinc tungstate (ZnWO₄) quantum dots, and combinations thereof.

10. The radiation detector of claim 8, further comprising a visible light absorption layer configured to generate an electric signal upon absorbing the pulse of visible light;
wherein the electronic system is configured to detect the pulse of visible light through the electric signal.

11. The radiation detector of claim 10, wherein the visible light absorption layer is divided into discrete regions by a material opaque to visible light.

12. The radiation detector of claim 10, wherein the visible light absorption layer is divided into discrete regions by a material opaque to the radiation.

13. The radiation detector of claim 8, wherein the discrete blobs are separated by a material opaque to visible light.

14. The radiation detector of claim 8, wherein the discrete blobs are separated by a material opaque to the radiation.

15. The radiation detector of claim 8, wherein the electronic system is configured to count a number of particles of radiation absorbed by the discrete blobs by counting a number of pulses of visible light.

16. The radiation detector of claim 10, wherein the visible light absorption layer comprises a plurality of pixels.

17. The radiation detector of claim 16, wherein the electronic system comprises a counter configured to count a number of pulses of visible light received by a pixel of the plurality of pixels.

18. The radiation detector of claim 16, wherein at least one of the discrete blobs is within a footprint of each pixel.

19. The radiation detector of claim 10, wherein the electronic system comprises an analog-to-digital converter (ADC) configured to digitize the electric signal.

20. (canceled)

21. The radiation detector of claim 8, wherein the particle of radiation is an X-ray photon.

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)
